(19) United States
(12) Patent Application Publication
(10) Pub. No.: US 2025/0040446 A1
(43) Pub. Date: Jan. 30, 2025

(54) HIGH SENSITIVITY MAGNETIC SENSING MATRIX CHIP WITH TWO-DIMENSIONAL ELECTRONIC GAS CHANNEL STRUCTURE AND THE MANUFACTURING PROCESS

(71) Applicant: DALIAN UNIVERSITY OF TECHNOLOGY, Dalian (CN)

(72) Inventors: Huolin HUANG, Dalian (CN); Nannan Ding, Dalian (CN); Jianxun Dai, Dalian (CN); Kaiming Ma, Dalian (CN); Hui Huang, Dalian (CN); Pengcheng Tao, Dalian (CN); Yanhong Liu, Dalian (CN); Kairong Qin, Dalian (CN)

(21) Appl. No.: 18/463,259

(22) Filed: Sep. 7, 2023

(30) Foreign Application Priority Data
Jul. 25, 2023 (CN) 202310917836.7

(51) Int. Cl. H10N 52/80; H10N 52/00; H10N 52/01

(52) U.S. Cl. CPC H10N 52/80; H10N 52/01; H10N 52/101

(57) ABSTRACT

A high-sensitivity two-dimensional electron gas channel structure magnetic sensing matrix chip includes a magnetic sensing matrix, a shift register, and a back-end interface circuit. The magnetic sensing matrix includes several matrix units including substrate, buffer layer, channel layer, and barrier layer. A two-dimensional electron gas channel material heterojunction structure includes buffer layer, channel layer, and barrier layer on the substrate, and the horizontal Hall element and switching device are above the channel layer. The beneficial effects include a high sensitivity magnetic sensing matrix chip with two-dimensional electronic gas channel structure can be used for real-time, static and dynamic measurement of multi-dimensional magnetic field distribution under high temperature, high pressure, high radiation and other harsh environments to carry out structural and circuit innovation and production.

### RELATED APPLICATIONS

The present application claims priority from Chinese Application Number 202310917836.7, filed Jul. 25, 2023, the disclosure of which is hereby incorporated by reference herein in its entirety.

### TECHNICAL FIELD

The invention belongs to the technical field of semiconductor devices, in particular to a high sensitivity magnetic sensing matrix chip with two-dimensional electronic gas channel structure and the manufacturing process.

### BACKGROUND TECHNOLOGY

The accurate measurement of magnetic field is very important for our daily life, which involves the correct identification of position, speed, angle and other physical quantities, thus affecting the use of devices in power electronics, navigation and guidance, aerospace, biomedicine and other fields. Common measurement methods of magnetic field include Hall effect method, flux gate method, magnetoresistance effect method, NMR (nuclear magnetic resonance) method, superconducting effect method and magneto-optical effect method. With the development of generations of new semiconductor materials, Hall magnetic sensor has been greatly developed, its performance is increasingly excellent, which applied widely.

The first generation of semiconductor materials are silicon (Si) and germanium (Ge), the second are represented by gallium arsenide (GaAs), indium arsenide (InAs) and indium antimonide (InSb), and the third are represented by gallium nitride (GaN), silicon carbide (SiC), diamond, and zinc oxide (ZnO). Hall magnetic sensor made by the first generation of semiconductor materials (typical such as Si) has low mobility of the material itself, resulting in low sensitivity of the device. The band gap of the second generation semiconductor materials is narrower, which leads to performance degradation or failure of the device and other reliability problems under the high temperature more than 200° C. In recent years, the third generation of semiconductor materials have shown great potential in photoelectric devices, power electronics, RF (radio frequency) and microwave devices, lasers and detector and its wide band gap, high breakdown electric field, high thermal conductivity, high electron saturation speed, low dielectric constant and other unique properties make devices have high thermostability, high voltage resistance, high radiation resistance, high sensitivity. Even in the harsh environment can also be effectively applied. Hall magnetic sensors made of the third generation semiconductor materials have good chemical stability and excellent reliability in high temperature environment due to the wide band gap. Especially taking gallium nitride (GaN) Hall magnetic sensor as an example, its band gap is 3.47 eV, ensuring the devices have high stability and reliability in high temperature environment, its heterojunction structure has naturally formed two-dimensional electron gas (2DEG) channels with high mobility, ensuring the devices have high sensitivity; its lower intrinsic carrier concentration ensures lower noise of the devices.

At present, Hall magnetic sensors made of the silicon (Si), germanium (Ge) and other traditional materials occupy a larger market share, and are often used at the single point measurement state for static magnetic field. However, the magnetic field distribution in the dynamic magnetic field and one-dimensional, two-dimensional, or even three-dimensional space cannot be measured. Therefore, it is necessary to use multi-dimensional matrix distributed Hall magnetic sensor to achieve multi-points measurement for the magnetic field in real time. At the same time, due to the disturbance from the position, angle or other factors of the sensor, there is usually a large measurement error at the single point measurement state, it is necessary to use the back-end interface circuit to compensate the error properly. Therefore, it's important to design a multi-dimensional matrix distributed Hall sensor with high sensitivity and high accuracy to achieve multi-points measurement for the magnetic field in real time. On the one hand, the dynamic magnetic field can be measured and the magnetic field distribution can be observed in real time. On the other hand, static magnetic field can be measured. The measurement error of magnetic field can be compensated by the matrix distributed Hall magnetic sensor, which simplifies the circuit and improves the measurement accuracy at the same time.

The existing Hall magnetic sensors are mostly linear horizontal Hall magnetic sensors measuring the magnetic field perpendicular to the surface of the device, which mainly include three kinds. One is the Hall sensor processed by the single material represented by Si material, with relatively mature process and easy to integrate. However, due to the low mobility of Si material itself, the sensitivity of this kind of Hall sensor is often relatively lower. The more mature products on the market are Infineon's TLE499X series, which are linear Hall sensors with integrated circuits, commonly used in the field of steering torque sensing. The second kind of Hall sensor is based on the second generation of semiconductor (InAs, InSb, GaAs, etc.) heterojunction structure. It can obtain high sensitivity due to the high mobility of 2DEG at the interface of the heterojunction, but limited to the narrow band gap, the device cannot work stably and reliably in the high temperature environment. The more mature products in the market are HW series, HG series and HQ series products from the Asahi Kasei Group. HW series are InSb Hall sensors with the highest sensitivity, HG series are the GaAs Hall sensors with stable temperature characteristics and the HQ series are the InAs Hall sensors with relatively balanced sensitivity and temperature characteristics among the three series. The third is the Hall sensor based on the third generation of semiconductor (GaN, etc.) heterojunction structure with unique properties, such as wide band gap, high breakdown electric field, high thermal conductivity, high electron saturation speed, and low dielectric constant, making devices have the characteristics of high thermostability, voltage resistance, radiation resistance, and sensitivity so as to effectively applied even in harsh environments. But there is no mature product on the market. The three kinds of Hall magnetic sensors can only be used for the single point measurement of static magnetic field, and the magnetic field distribution in the dynamic magnetic field and one-dimensional, two-dimensional, or even three-dimensional space cannot be measured. At the same time, due to the disturbance from the position, angle or other factors of the sensor, the single point measurement usually has a large measurement error, it is necessary to use the back-end interface circuit to properly compensate the error.

To sum up, it is more necessary to use the multi-dimensional matrix distributed Hall magnetic sensors integrated with subsequent interface circuit to detect the magnetic field distribution in real time or multi-point measurement (including the magnetic field distribution under high temperature, high voltage and high radiation environment). On the one hand, the dynamic magnetic field can be detected and the magnetic field distribution can be observed in real time. On the other hand, the static magnetic field can be measured. The measurement error of the magnetic field can be compensated by the matrix distributed Hall magnetic sensor, which simplifies the circuit and improves the measurement accuracy.

Hall magnetic sensors are often used in the single point detection, for the magnetic field distribution in the dynamic magnetic field and one-dimensional, two-dimensional, or even three-dimensional space cannot be measured, so it is essential to use multi-dimensional matrix distributed Hall magnetic sensor to detect and measure the magnetic field by multiple points in real time. Simultaneously, at the state of single point measurement, there is usually a large measurement error due to the disturbance of the position, angle and other factors of the sensor, so it is available to use the back-end interface circuit to properly compensate the error.

### SUMMARY

In order to solve the problems in the above existing technologies, the invention proposes a high sensitivity magnetic sensing matrix chip with two-dimensional electronic gas channel structure, including its structure, circuit and manufacturing process. The technical scheme can be used for real-time, static and dynamic measurement of the magnetic field distribution perpendicular to the surface of the device, and carry out innovation and fabrication in structure and circuit. It can realize the dynamic and static measurement of magnetic field in multi-dimensional space, and conduct error compensation through the circuit, which not only ensures the chip can work stably, but also ensures it has high linearity, sensitivity and accuracy.

The technical scheme is as follows:

A high sensitivity magnetic sensing matrix chip with two-dimensional electronic gas channel structure, including: magnetic sensing matrix, shift register, back-end interface circuit. The shift register controls the turn-on and turn-off of switching devices in the matrix units. The magnetic sensing matrix includes several matrix units comprising substrate, buffer layer, channel layer, and barrier layer. A two-dimensional electron gas channel material heterojunction structure composed of buffer layer, channel layer, and barrier layer is grown on the substrate, and the horizontal Hall element and switching device are arranged above the channel layer. The main body of the horizontal Hall element is composed of the cross-shaped barrier layer, with electrodes C1, C2, S1 and S2 respectively arranged at the four ends of the cross-shaped barrier layer. The switching device comprises a gate electrode G, a source electrode S, and a drain electrode D. The source electrode S and drain electrode D are arranged on the channel layer, and the channel layer is provided with dielectric layer extending to the barrier layer. The gate electrode G is arranged above the dielectric layer. The electrode C2 is connected to the source electrode S through the metal interconnection line.

Further, the substrate is one of Si, SiC, and sapphire, or the homogeneous material with the channel layer; the buffer layer is one of AlN, and GaN, or a superlattice structure material.

Further, the channel layer is one of GaN, GaAs, InSb, InAs, and GaO; the barrier layer is the heterojunction material forming a two-dimensional electron gas channel with the channel layer.

Further, the dielectric layer is one of Al₂O₃, Si₃N₄, SiO₂, and SiON; the metal interconnection line adopts one of copper, tungsten, aluminum and cobalt.

Further, the thickness of the buffer layer is 10˜100 nm; the thickness of the channel layer is 0.1˜10 μm; the thickness of the barrier layer is 5˜100 nm; the thickness of the dielectric layer is 20˜50 nm.

The invention also proposes a type of circuit of the high sensitivity magnetic sensing matrix chip with two-dimensional electronic gas channel structure, including: the power supply module, excitation power supply circuit, reference voltage source circuit, adjustable gain amplifier circuit, voltage regulation circuit, AD conversion circuit, microprocessor, shift register, and magnetic sensing matrix. The power supply module is respectively connected with the reference voltage source circuit and the microprocessor. The reference voltage source circuit is connected with the excitation power supply circuit, the adjustable gain amplifier circuit and the voltage regulation circuit respectively. Moreover, the excitation power supply circuit is sequentially connected with the magnetic sensing matrix, adjustable gain amplifier circuit, voltage regulation circuit, AD conversion circuit, and microprocessor. It should be noted that the shift register connect the magnetic sensing matrix, which is controlled by microprocessor to generate switching selection signal so as to realize the on and off of switching devices in the row and column.

Further, the magnetic sensing matrix includes several matrix units comprising substrate, buffer layer, channel layer, and barrier layer. A two-dimensional electron gas channel material heterojunction structure composed of buffer layer, channel layer, and barrier layer is grown on the substrate, and the horizontal Hall element and switching device are arranged above the channel layer. The main body of the horizontal Hall element is composed of the cross-shaped barrier layer, with electrodes C1, C2, S1 and S2 respectively arranged at the four ends of the cross-shaped barrier layer. The switching device comprises a gate electrode G, a source electrode S, and a drain electrode D. The source electrode S and drain electrode D are arranged on the channel layer, and the channel layer is provided with a dielectric layer extending to the barrier layer. The gate electrode G is arranged above the dielectric layer. The electrode C2 is connected to the source electrode S through the metal interconnection line.

The invention also includes a method for manufacturing the high sensitivity magnetic sensing matrix chip with two-dimensional electronic gas channel structure comprising the following steps:
S1. Clean the substrate: prepare substrate material, clean substrate, and remove contaminants on the surface of substrate.
S2. Epitaxial growth: epitaxially growing a two-dimensional electron gas channel material heterojunction structure and a buffer layer by any one of a metal organic compound chemical vapor deposition method, a molecular beam epitaxy method, and a hydride vapor phase epitaxy method.
S3. Mesa etching: after photolithography and development, the epitaxially grown samples are etched by inductively coupled plasma etching.
S4. Shallow etching: the sample after mesa etching and isolation, after photolithography and development, are subjected to shallow etching by inductively coupled plasma etching to realize 2DEG contacting the mesa.
S5. Fabrication of electrodes by Ohmic contact: after photolithography and development, composite metal is deposited by electron beam evaporation system, and then an excellent ohmic contact is formed by using a rapid thermal annealing process.
S6. Gate groove etching: after the electrodes C1, C2, S1, S2, source S, and drain D are prepared, the gate groove etching is carried out by inductively coupled plasma etching method.
S7. Gate dielectric deposition: after the sample subjected by gate groove etching is subjected to gate-groove interface treatment using an alkaline solution with nitrogen element, the gate dielectric is deposited by any one of the methods of metal-organic chemical vapor deposition, plasma chemical vapor deposition, atomic layer deposition, low pressure chemical vapor deposition, and magnetron sputtering.
S8. Fabrication of gate electrode: after photolithography and development, composite metal is deposited by electron beam evaporation system, and the metal is stripped to form gate electrode.
S9. Surface passivation: use any one of the methods of plasma enhanced chemical vapor deposition, magnetron sputtering, atomic layer deposition, and electron beam evaporation to deposition SiO₂ for device passivation.
S10. Electrodes windowing: photoetching and corroding the passivation layer at the electrode to form electrode windows.
S11. Fabrication of metal interconnection lines: after photolithography and development, use electron beam evaporation system to deposit metal to form interconnection lines.
S12. Wire bonding of electrodes: use any one of the methods of magnetron sputtering, electron beam evaporation, and thermal evaporation to deposit metal to make pads and wire bonding.

Further, in step S2, the thickness of the grown channel layer is 0.1˜10 μm, the thickness of the barrier layer grown on the channel layer is 5˜100 nm, and the buffer layer is AlN, GaN or other superlattice structures and the thickness is 10˜100 nm.

Further, in step S3, the mesa etching depth is 50˜800 nm; in step S4, the etching depth is 1˜100 nm; in step S6, the etching depth is 1˜100 nm; and in step S7, the deposition thickness is 5˜50 nm.

The beneficial effects of the invention are:

A high sensitivity magnetic sensing matrix chip with two-dimensional electronic gas channel structure and the manufacturing process proposed by the invention has the following characteristics:
1) The device structure is simple and diverse, can be made of heterojunction structure composed of GaAs/AlGaAs, GaN/AlGaN, InAs/InGaAs, Ga₂O₃/AlGaO and other materials, the natural 2DEG channel makes devices highly sensitive, the high electron mobility (the electron mobility of GaAs and InAs can reach 9000 cm²/(V·s) and 40000 cm²/(V·s) respectively) makes devices have excellent electron transport performance in low and high fields, which is ideal channel material for ultra-high speed and low-power sensing devices.
2) Typical devices made from 2DEG channel materials show great potential in optoelectronic devices, power electronics, radio frequency microwave devices, lasers and detector components, such as GaN materials, whose unique properties, such as large band gap, high breakdown electric field, high thermal conductivity, high electron saturation speed, low dielectric constant, make the prepared devices have the characteristics of high temperature resistance, high voltage resistance, high radiation resistance, high sensitivity. What's more important, it can be effectively applied even in harsh environments.
3) The magnetic sensing matrix chip is composed of magnetic sensing matrix with several matrix units, shift register and back-end interface circuit. Each matrix unit contains a cross-shaped horizontal Hall element and a switching device. Each switching device is controlled by row and column signals generated by shift register in order to control the turn-on and turn-off of the Hall element excitation loop. The whole system has simple structure and flexible operation.
4) The magnetic sensing matrix chip with 2DEG channel structure can not only measure static magnetic field accurately, but also measure the dynamic magnetic field and observe the magnetic field distribution in real time. It is easy to integrate with the circuit and the back-end interface circuit ensures the scanning and acquisition of the output Hall signal of each matrix unit. At the same time, the output voltage of multiple matrix units can realize the compensation of the output voltage of other matrix units, which simplifies the circuit and improves the sensitivity and accuracy.

The beneficial effects brought by the technical scheme of the invention are as follows:
1) The simple structure of combining the Hall element with switching device into the matrix unit can flexibly realize the real-time, static and dynamic measurement of the magnetic field perpendicular to the direction of the device in one-dimensional, two-dimensional or even three-dimensional space, which is not available in a single Hall sensor.
2) The device can be made of 2DEG channel materials (such as GaN material), whose unique properties ensure the prepared devices operate stably in harsh environments such as high temperature (up to 400° C.), high pressure (up to 1000V), and high radiation, which is not possessed by sensors made of narrow bandgap materials such as first generation semiconductors (such as Si and Ge)
3) The integration of the chip and the circuit has greatly improved the performance of the device, ensuring that the sensitivity of the device increase significantly under the condition that the measured magnetic field range is unchanged, and the maximum is 16.5 mV/mT (the measured magnetic field range is −100 mT˜100 mT, and the excitation current is 1 mA), which is nearly 300 times that of a single third-generation semiconductor Hall sensor (for example, the sensitivity of a single GaN horizontal Hall sensor is 0.06 mV/mT under 1 mA excitation current), and the linearity reaches 99.969%.

### BRIEF DESCRIPTION OF DRAWINGS

In order to explain the technical solution of the embodiments of the invention more clearly, the invention will be described in detail in combination with the diagrams and detailed embodiments. It is obvious that the diagrams in the following description are only some embodiments of the invention. For ordinary technicians in this area, other diagrams can also be obtained from these diagrams without creative work. Among them:

FIG. 1 is the vertical view of the high sensitivity magnetic sensing matrix chip with two-dimensional electronic gas channel structure proposed in the application (only a single matrix unit is shown);

FIG. 2 is the front view of the high sensitivity magnetic sensing matrix chip with two-dimensional electronic gas channel structure proposed in the application of the invention (only a single matrix unit is shown);

FIG. 3 is the structure block diagram of the back-end interface circuit of the high sensitivity magnetic sensing matrix chip with two-dimensional electronic gas channel structure (including shift register) proposed in the application of;

FIG. 4 to FIG. 15 is a schematic diagram of the technology realization process of the high sensitivity magnetic sensing matrix chip with two-dimensional electronic gas channel structure proposed in the application;

FIG. 16 to FIG. 27 is the technology flow diagram of a specific embodiment of this application;

FIGS. 28A and 28B are the experimental verification result diagram of the relationship between the magnetic field B and the Hall output voltage Vₒ of each matrix unit under the static measurement of the high sensitivity magnetic sensing matrix chip with two-dimensional electronic gas channel structure proposed in the application;

FIGS. 29A and 29B are the experimental verification result diagram of the relationship between the Hall output voltage of a single matrix unit and the magnetic field under the sinusoidal magnetic field with the peak-to-peak value of Bp-p of 17.798 G and the frequency of 5 Hz for the high sensitivity magnetic sensing matrix chip with two-dimensional electronic gas channel structure proposed in the application of the invention

### EXAMPLES

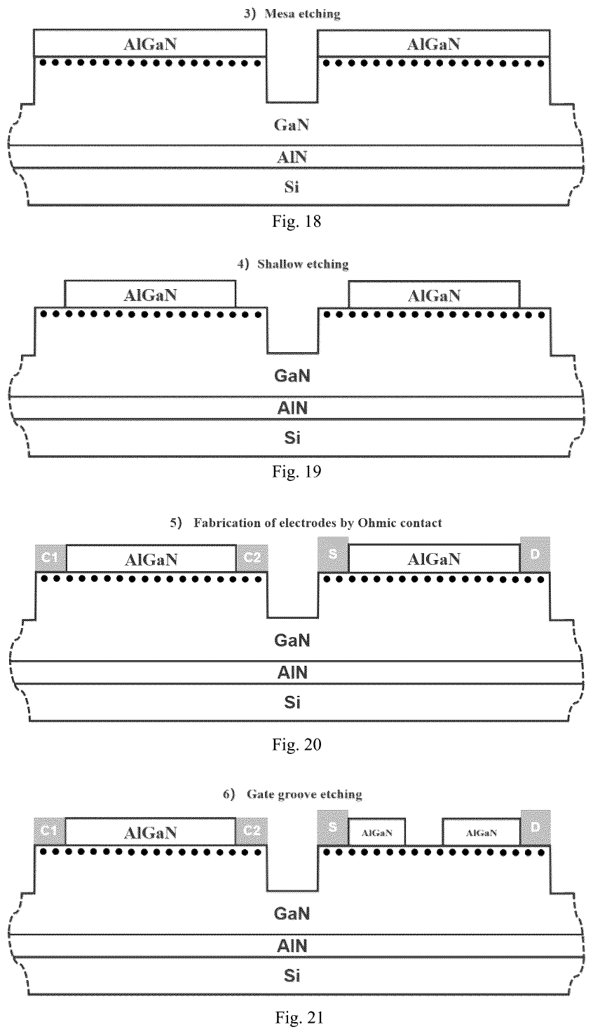

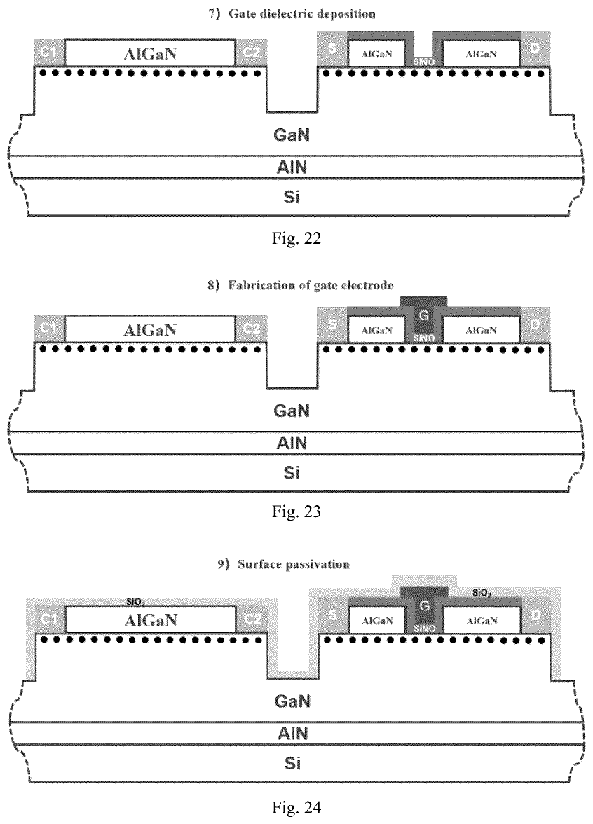

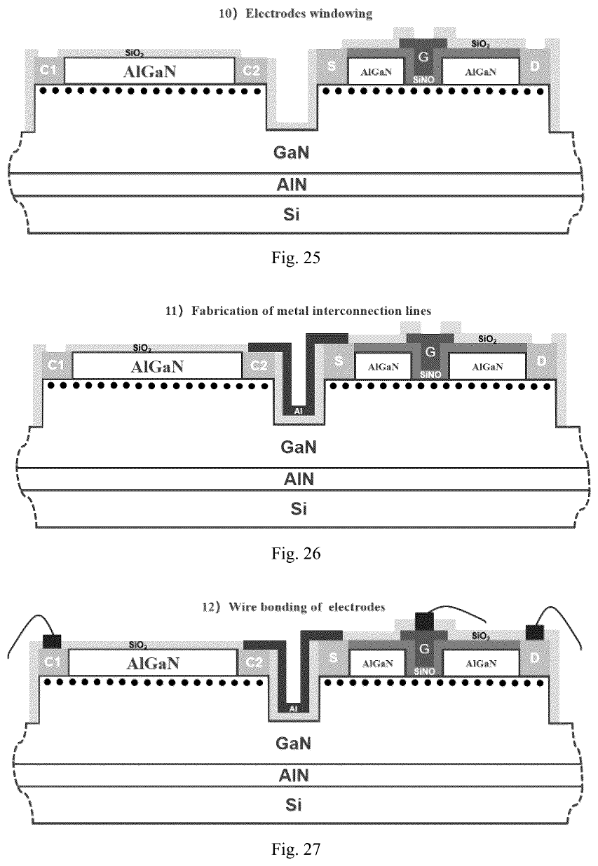

In order to make the purpose, technical scheme and advantages of the invention clearer, the invention will be further described in detail with the attached drawings and embodiments. It should be understood that the specific embodiments described herein are only used to explain the invention but not to limit the invention. A high sensitivity magnetic sensing matrix chip with two-dimensional electronic gas channel structure and the manufacturing process are further described with reference to FIG. 16 to FIG. 27 below.

### Embodiment 1

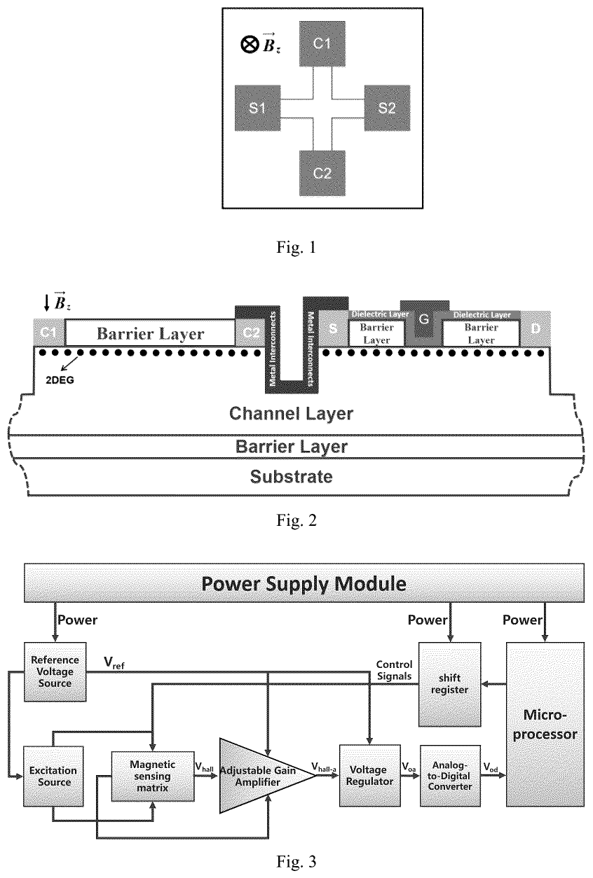

In order to solve the problems existing in the above technologies and realize the real-time, dynamic and static measurement of the magnetic field perpendicular to the device surface under the high temperature, high voltage and high radiation environment, the invention applies for the technical proposal of a high sensitivity magnetic sensing matrix chip with two-dimensional electronic gas channel structure and the manufacturing process. The technical proposal includes chip structure, circuit and fabrication method. FIG. 1 shows the schematic diagram of the chip structure, which is composed of magnetic sensing matrix, shift register and back-end interface circuit. Each matrix unit contains a cross-shaped horizontal Hall element and a switching device. The Hall element is made of 2DEG channel material based on Hall effect. Due to the spontaneous polarization and piezoelectric polarization effects, 2DEG with high electron mobility (typical value is 2000 cm²/V·s) without intentional doping is generated at the heterojunction interface, which makes devices have high sensitivity. As shown in FIG. 1 and FIG. 2, electrodes C1 and C2 are excitation signal input terminals which can input voltage V_{bias} or current I_{bias}, and measure the potential difference between electrodes S1 and S2 as hall output voltage Vₕₐₗₗ. It is also feasible that use electrodes S1 and S2 as signal input terminals to input voltage or current, and measure the potential difference between electrodes C1 and C2 as hall output voltage. The switch of each switching device is controlled by the shift register, thereby controlling the on or off of the excitation loop of the matrix element. A plurality of matrix units are arranged in Determinant to form magnetic sensing matrix chip.

In addition, in order to reduce the measurement error and realize real-time, static and dynamic measurement of magnetic field distribution, the back-end interface circuit is built. As shown in FIG. 3, the back-end interface circuit structure block diagram includes power supply module, excitation power supply circuit, reference voltage source circuit, adjustable gain amplifier circuit, voltage regulation circuit, AD conversion circuit, microprocessor, and shift register. The power supply module supplies power to the whole chip system. The excitation power supply circuit supplies excitation current or voltage to the magnetic sensing matrix. The microprocessor controls the shift register to output corresponding signals that control the switch of one or more switching devices, so that the excitation loops in the corresponding matrix units are on or off. The reference voltage source circuit provides the reference voltage V_{ref} for the adjustable gain amplifier circuit and voltage conversion circuit. The adjustable gain amplifier circuit amplifies the output voltage Vₕₐₗₗ of the Hall element, and the adjustable amplification circuit factor enables the device to accurately measure various specific magnetic field ranges. The voltage regulation circuit adjusts the amplified hall output voltage to the voltage range that can be recognized by the AD conversion circuit, thus converting the analogue hall output voltage signal Vₒₐ to the digital Hall output voltage signal V_{od}. Finally, the hall output voltage signal Vₒ of each matrix unit is sent to the microprocessor for signal analysis and processing, such as using other matrix units to compensate the hall output voltage of a single matrix unit to reduce the measurement error, outputting the results of multiple matrix units after weighted average processing, and drawing a one-dimensional or multi-dimensional magnetic field distribution map for the hall output voltage of all matrix units.

The technology structure of the technical solution applied by the invention is shown in FIG. 1 and FIG. 2. In order to explain the technology structure more clearly, a single matrix unit is only shown. The chip structure comprises substrate, buffer layer, channel layer, barrier layer, dielectric layer, metal interconnection lines, and electrodes which include C1, C2, S1, S2, gate G, source S, drain D. The substrate is silicon, silicon carbide, sapphire or other homogeneous material with the channel layer. The buffer layer and 2DEG channel material heterojunction structure epitaxially grow on the substrate. The heterojunction structure includes the channel layer and barrier layer. The 2DEG is formed between the interface of the heterojunction due to the spontaneous polarization and piezoelectric polarization effects. The buffer layer is one of AlN, GaN, or other superlattice structure material (the thickness is 10˜100 nm). The channel layer is one of GaN, GaAs, InSb, InAs, GaO (the thickness is 0.1˜10 μm) and the barrier layer is one of AlGaN, InGaAs, AlGaAs, InAlN, AlGaO or other heterojunction material (the thickness is 5˜100 nm) that can form 2DEG channel with the channel layer. The material components in the barrier layer are not limited. Besides, the dielectric layer is one of Al₂O₃, Si₃N₄, SiO₂, SiON or other oxides or nitrides (the thickness is 20˜50 nm), and the metal interconnection lines usually use copper, tungsten, aluminum, cobalt or other metals. The electrodes C1, C2, S1, S2 of the Hall element, and the gate G, source S, and drain D of the switching device in each matrix unit are the same. The electrode shape is not subject to special restrictions, but can be rectangular, trapezoidal, etc. In addition to gate G, other electrodes need to form excellent ohmic contact with semiconductor materials.

The Operating principle of the high sensitivity magnetic sensing matrix chip with two-dimensional electronic gas channel structure proposed by the invention application is as follows: When the magnetic field B_{z} in the environment is perpendicular to the device surface, the shift register controls the switching device of any matrix unit to turn on. Currently, there is excitation voltage or excitation current flowing into the excitation electrodes C1 and C2 of Hall element in the corresponding matrix unit, so that the hall output voltage signal is induced at the output electrodes S1 (V_{Hall+}) and S2 (V_{Hall-}), which is sent to the back-end interface circuit for a series of signal processing, including filtering, amplification and output. It can realize the magnetic field measurement at the specified position, dynamic magnetic field scanning, and multi-dimensional magnetic field distribution measurement perpendicular to the chip direction.

The technology scheme of the high sensitivity magnetic sensing matrix chip with two-dimensional electronic gas channel structure proposed by the invention has the following characteristics: 1) The device structure is simple and diverse, can be made of heterojunction structure composed of GaAs/AlGaAs, GaN/AlGaN, InAs/InGaAs, Ga₂O₃/AlGaO and other materials, the natural 2DEG channel makes devices highly sensitive, the high electron mobility (the electron mobility of GaAs and InAs can reach 9000 cm²/(V·s) and 40000 cm²/(V·s) respectively) makes devices have excellent electron transport performance in low and high fields, which is ideal channel material for ultra-high speed and low-power sensing devices. 2) Typical devices made from 2DEG channel materials show great potential in optoelectronic devices, power electronics, radio frequency microwave devices, lasers and detector components, such as GaN materials, whose unique properties, such as large band gap, high breakdown electric field, high thermal conductivity, high electron saturation speed, low dielectric constant, make the prepared devices have the characteristics of high temperature resistance, high voltage resistance, radiation resistance, high sensitivity. What's more important, it can be effectively applied even in harsh environments. 3) The magnetic sensing matrix chip is composed of magnetic sensing matrix with several matrix units, shift register and back-end interface circuit. Each matrix unit contains a cross-shaped horizontal Hall element and a switching device. Each switching device is controlled by row and column signals generated by shift register in order to control the turn-on and turn-off of the Hall element excitation loop. The whole system has simple structure and flexible operation. 4) The magnetic sensing matrix chip with 2DEG channel structure can not only measure static magnetic field accurately, but also measure the dynamic magnetic field and observe the magnetic field distribution in real time. It is easy to integrate with the circuit and the back-end interface circuit ensures the scanning and acquisition of the output Hall signal of each matrix unit. At the same time, the output voltage of multiple matrix units can realize the compensation of the output voltage of other matrix units, which simplifies the circuit and improves the sensitivity and accuracy.

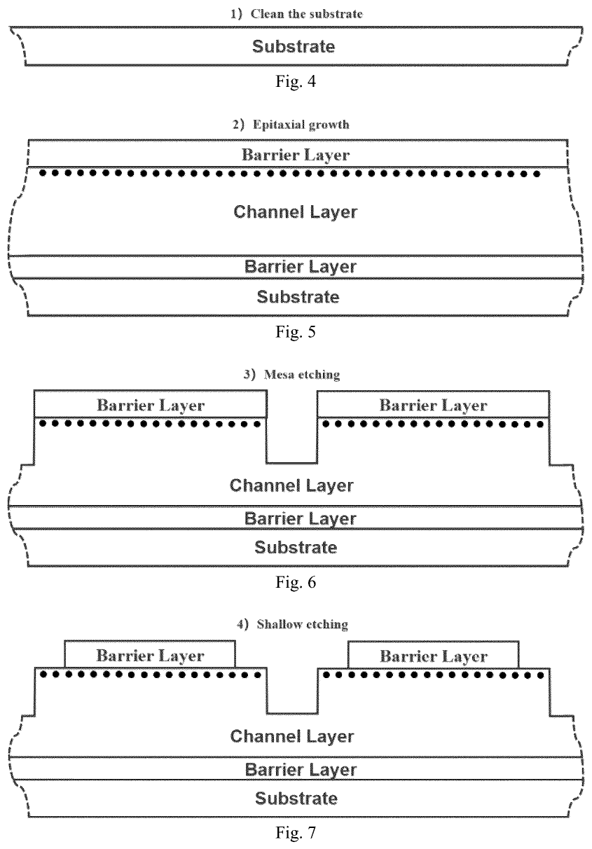

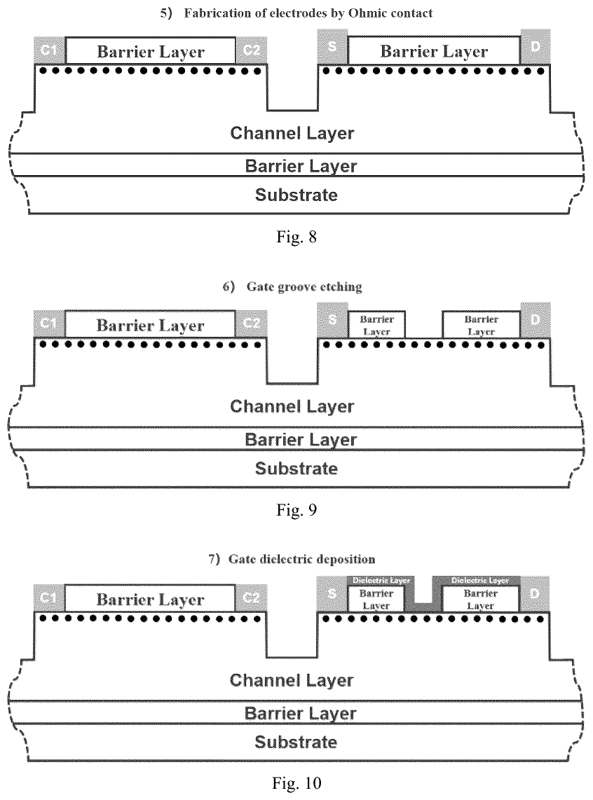

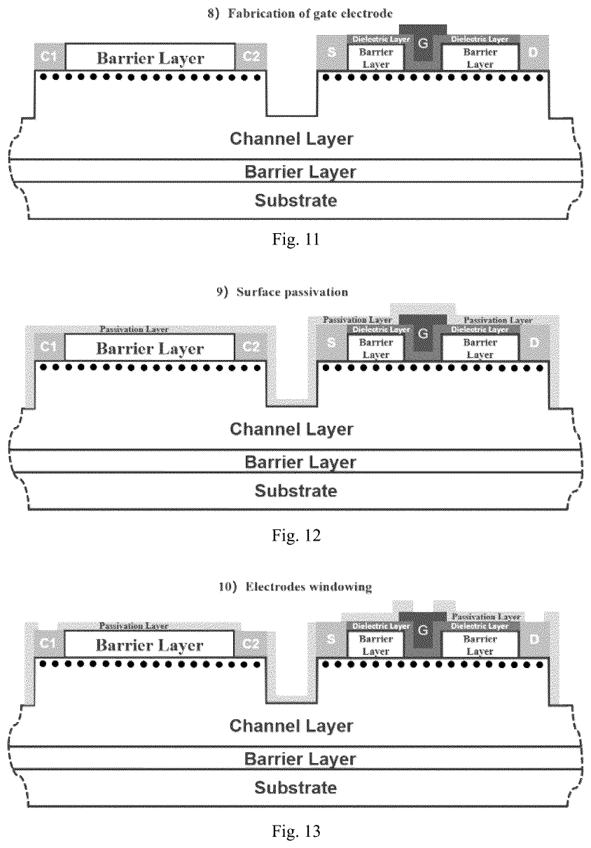

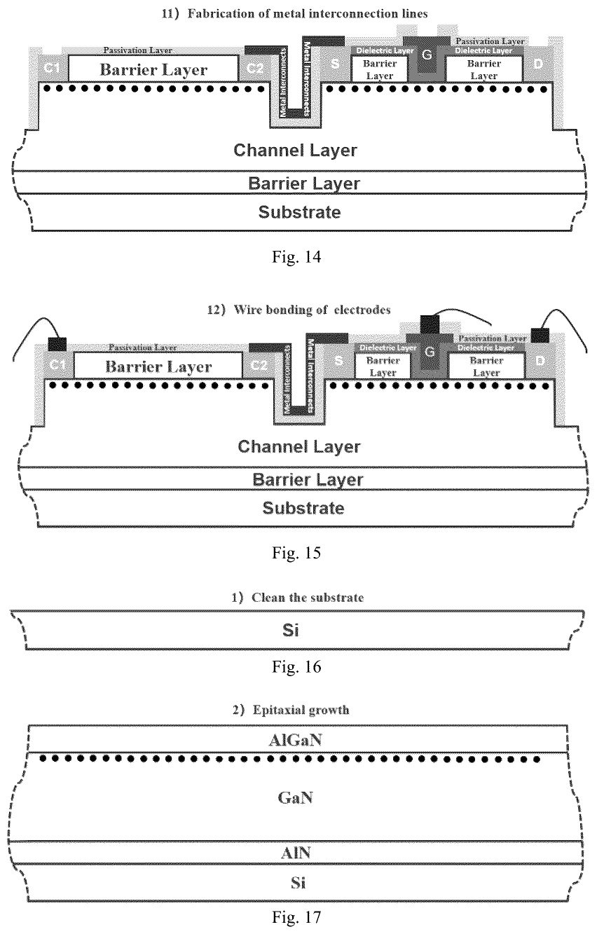

As shown in FIG. 4 to FIG. 15, the technological realization process of the target device applied by the invention is described as follows:
(1). Clean the substrate: prepare 4-inch or 6-inch substrate material, clean the substrate and remove contaminants from the substrate surface.
(2). Epitaxial growth: The heterojunction structure and buffer layer of 2DEG channel material are grown by using any one of the methods of metal-organic chemical vapor deposition (MOCVD), molecular beam epitaxy (MBE) and hydride vapor phase epitaxy (HVPE), and the thickness of the channel layer is 0.1˜10 μm. The barrier layer on the channel layer is 5˜100 nm thick, and the buffer layer can be AlN, GaN or other superlattice structure material, with a thickness of 10˜100 nm.
(3). Mesa etching: after photolithography and development, the epitaxial samples are etched by inductively coupled plasma etching and the depth of mesa etching is 50˜800 nm.
(4). Shallow etching: after the samples isolated by mesa etching are developed and photolithographic, the inductively coupled plasma etching method is used for shallow etching, which makes 2DEG of heterogeneous interfaces contact mesa and the depth of etching is 1˜100 nm.
(5). Fabrication of Ohmic contact electrodes: after photolithography and development, composite metal is deposited by electron beam evaporation system, and then excellent ohmic contacts are formed by rapid thermal annealing process.
(6). Gate groove etching: after the electrodes C1, C2, S1, S2, source S, and drain D are prepared, the gate groove etching is carried out by inductively coupled plasma etching method with the etching depth of 1˜100 nm.
(7). Gate dielectric deposition: after burnishing the gate and groove interface of the sample using the alkaline solution containing nitrogen element, the gate dielectric is deposited by one of the methods of metal-organic chemical vapor deposition, plasma chemical vapor deposition, atomic layer deposition, low pressure chemical vapor deposition, and magnetron sputtering and the thickness of deposition is 5˜50 nm.
(8). Fabrication of gate electrode: after photolithography and development, the composite metal is deposited by electron beam evaporation system, and the metal is stripped to form gate electrode.
(9). Surface passivation: use one of the methods of plasma enhanced chemical vapor deposition, magnetron sputtering, atomic layer deposition, electron beam evaporation to deposition SiO₂ for device passivation.
(10). Electrodes windowing: photoetching and corroding the passivation layer at the electrode to form electrode windows.
(11). Fabrication of metal interconnection lines: after photolithography and development, use electron beam evaporation system to deposit metal to form interconnection lines.
(12). Wire bonding of electrodes: use any one of the methods of magnetron sputtering, electron beam evaporation, thermal evaporation to deposit metal on the electrodes to make pads and wire bonding.

The technical key points of the invention are:

Firstly, a high sensitivity magnetic sensing matrix chip with two-dimensional electronic gas channel structure is proposed. It is no longer a single horizontal Hall sensor that can measure the magnetic field perpendicular to the device surface, but connects multiple horizontal Hall elements with switching devices to form N×M (The specific value of N and M can be determined according to the distribution of the measured magnetic field) matrix units. The switching devices control the acquisition of hall output signals flexibly, thus realizing the measurement of the magnetic field distribution in one-dimensional, two-dimensional or even three-dimensional space, which is an innovation in structure.

Secondly, the device can be made of 2DEG channel materials (such as GaN material), whose unique properties ensure the prepared devices operate stably in harsh environments such as high temperature (up to 400° C.), high pressure (up to 1000V), and high radiation in aerospace environments especially, which is an innovation in applicability. In addition, the device is fabricated by heterostructure structure composed of two-dimensional electronic gas channel materials (such as GaAs/AlGaAs, GaN/AlGaN, InAs/InGaAs, Ga₂O₃/AlGaO, etc). It has the high concentration of two-dimensional electronic gas (2DEG) at the heterostructure interface, and the high electron mobility (the electron mobility of GaAs and InAs can reach 9000 cm²/(V·s) and 40000 cm²/(V·s) respectively), making devices have excellent electron transport performance in low and high fields, which is also an innovation in applicability.

Furthermore, the chip is easy to integrate with the back-end interface circuit and the chip structure is uncomplicated. It realizes multi-point measurement using multiple matrix units and improves the sensitivity and accuracy of the device, which is an innovation in performance.

Therefore, the invention application requires patent protection for the proposed chip structure design, circuit structure and manufacturing process.

### Embodiment 2

The target device applied by the invention is a high sensitivity magnetic sensing matrix chip with two-dimensional electronic gas channel structure composed of 1×N (The specific value of N can be determined according to the distribution of the measured magnetic field) matrix units. The embodiment is composed of 1×10 matrix units and the chip is made of AlGaN/GaN heterostructure. Since the structure and technology of each matrix unit are the same, this embodiment only shows the technology process of a single matrix unit, as shown in FIG. 16 to FIG. 27. The technology process flow is described as follows:
(1). Clean the substrate: prepare Si substrate, clean the substrate and remove contaminants from the substrate surface.
(2). Epitaxial growth: The AlGaN/GaN heterojunction structure and the buffer layer were epitaxial grown by metal organic compound chemical vapor deposition (MOCVD). The GaN epitaxial layer was unintentionally doped with a thickness of 5 μm. The background electron concentration is less than 1×10¹⁷ cm⁻³, the thickness of the AlGaN barrier layer on the epitaxial layer is 25 nm, and the Al component is 0.25. The buffer layer is AlN with the thickness of 50 nm.
(3). Mesa etching: after spin-coating photoresist (using AZ6130 positive photoresist) that the rotational speed of the previous step is 600 rpm-3 s, and the next step is 1000 rpm-20 s to form the final photoresist with the thickness of 2 μm, photolithography, and development (90 seconds), the heterojunction is etched by inductively coupled plasma etching (ICP), with the etching power of 200 W, and the 150 sccm Cl-based gas is injected for 250 s etching, finally forming the etching depth of about 400 nm.
(4). Shallow etching: after spin-coating photoresist (using AZ6130 positive photoresist) that the rotational speed of the previous step is 600 rpm-3 s, and the next step is 1000 rpm-20 s to form the final photoresist with the thickness of 2 μm, photolithography, and development (90 seconds), the heterojunction is etched by inductively coupled plasma etching (ICP), with the etching time of 30 seconds and the etching rate of 55 nm/min, finally forming the etching depth of about 25 nm.
(5). Fabrication of electrodes by Ohmic contact: after photolithography and development, Ti (20 nm)/Al (100 nm)/Ni (45 nm)/Au (55 nm) four layers of metal is deposited sequentially by electron beam evaporation system, and then excellent ohmic contacts are formed by rapid thermal annealing process in nitrogen at 850° C. for 30 s.
(6). Gate groove etching: after preparing electrodes C1, C2, S1, S2, source S, drain D, the sample is carried out by gate groove etching through inductively coupled plasma etching method until the thickness of the remaining AlGaN is 5 nm.
(7). Gate dielectric deposition: after the sample subjected by gate groove etching is subjected to gate and groove interface treatment using the alkaline solution with nitrogen element, the gate dielectric SiON is deposited by plasma chemical vapor deposition (PECVD) method and the thickness of deposition is 20 nm.
(8). Fabrication of gate electrode: after photolithography and development, Ti (20 nm)/Al (100 nm)/Ni (45 nm)/Au (55 nm) four layers of metal is deposited by electron beam evaporation system, and the metal is stripped to form gate electrode.
(9). Surface passivation: the plasma enhanced chemical vapor deposition (PECVD) method is used to deposit SiO₂ passivation layer with the thickness of 300 nm at 300° C. to weaken the influence of ambient atmosphere for device characteristics.
(10). Electrodes windowing: The passivation layer at the electrode is corroded and the window is opened for wire bonding. After spin-coating photoresist (using AZ6130 positive photoresist) that the rotational speed of the previous step is 600 rpm-3 s, and the next step is 1000 rpm-20 s to form the final photoresist with the thickness of 2 μm, photolithography, and development (90 seconds), the sample is etched at the electrode after surface passivation using ICP etching to form a window.
(11). Fabrication of metal interconnection lines: after photolithography and development, use magnetron sputtering method to deposit 500 nm metal Al and the metal is stripped to form interconnection lines.
(12). Electrodes wire: use magnetron sputtering to deposit 500 nm Al on the electrodes, and then lead the electrodes out.
(13). Dicing and cutting: scribe and cut the prepared 4-inch or 6-inch wafers with a wafer cutting machine, and select each complete and scratch-free chip on the wafer.
(14). Wire bonding: stick the selected chip on the PCB substrate with epoxy glue, perform wire bonding on the output electrode of the Hall element in each matrix element on the chip, connect the bonding wire to the pad on the PCB substrate, this ensures that each Hall voltage output electrode is drawn out through the PCB substrate.
(15). Connection of circuit: connect PCB substrate carrying the magnetic sensor matrix, and each component of the back-end interface circuit on the same PCB substrate, to complete the circuit connection of the magnetic sensing matrix chip.

### Results

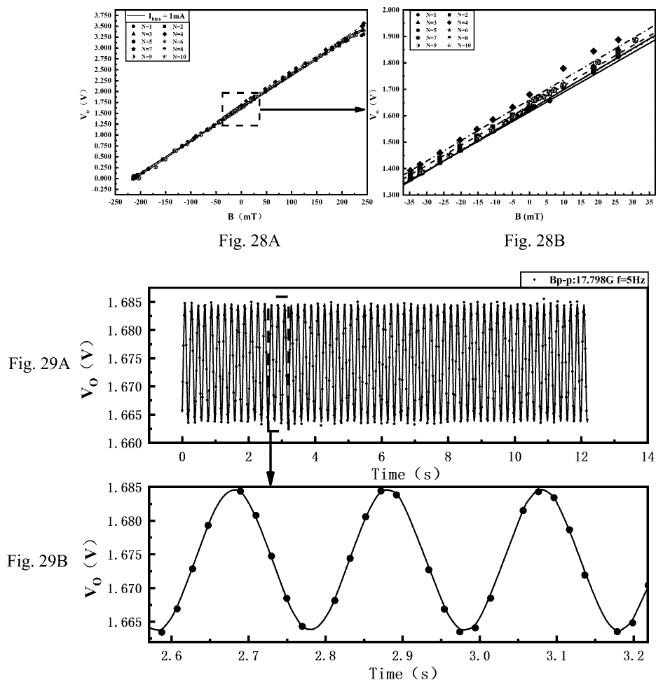

FIGS. 28A and 28B shows the relationship between magnetic field B and hall output voltage Vₒ of the Nth (N=1˜10) matrix unit in the magnetic sensing matrix chip applied for the design of the invention under static measurement, in which the excitation current I_{bias} equals to 1 mA, the gain A of adjustable gain amplifier is adjusted to a fixed value of 275, the reference voltage source provides the reference voltage V_{ref}=1.65V, and the measured magnetic field range is −250 mT˜250 mT. It can be seen from the figure that with the increase of the magnetic field in the environment, the hall voltage detected by each matrix unit through the back-end interface circuit also increases linearly, and the sensitivity of the 10 matrix units is basically the same, namely 7.73 mV/mT (N=1), 7.74 mV/mT (N=2), 7.74 mV/mT (N=3), 7.73 mV/mT (N=4), 7.72 mV/mT (N=5), 7.72 mV/mT (N=6), 7.72 mV/mT (N=7), 7.71 mV/mT (N=8), 7.71 mV/mT (N=9), 7.71 mV/mT (N=10), which is about 120 times that of a single third-generation semiconductor Hall sensor. In addition, the linearity is also high, reaching 99.898%, 99.969%, 99.928%, 99.941%, 99.899%, 99.999%, 99.999%, 99.902%. This shows that when the magnetic field distribution in the environment is different, each matrix unit can detect the amplitude of the magnetic field perpendicular to the device, which is reflected by the change of the hall output voltage Vₒ, so as to realize the accurate real-time and static measurement of the one-dimensional magnetic field distribution.

FIGS. 29A and 29B shows the relationship between the magnetic field B and the hall output voltage Vₒ of a single matrix unit of the chip applied by the invention under dynamic measurement, in where the magnetic field source provides a sinusoidal alternating magnetic field with the peak-to-peak value of Bp-p of 17.798 G and the frequency of 5 Hz, and other test conditions are the same as the static test conditions. It can be seen from the figure that the Hall voltage detected by the matrix unit through the back-end interface circuit follows the sine change of the magnetic field in the environment, and the sine change of the frequency of 5 Hz also occurs, which shows that each matrix unit can basically follow the change of the magnetic field in the environment without difference at a lower frequency, thus realizing the real-time dynamic measurement of the one-dimensional magnetic field distribution.

The above is only a better specific implementation of the invention, but the scope of protection of the invention is not limited to this. Within the scope of technology disclosed by the invention, any technical personnel familiar with the technical field who make equivalent replacement or change according to the technical scheme and the concept of the invention should be covered by the scope of protection of the invention.

1. A high sensitivity magnetic sensing matrix chip with a two-dimensional electronic gas channel structure comprising a magnetic sensing matrix, a shift register, and a back-end interface circuit, wherein the shift register is sequentially connected to the magnetic sensor matrix and the back-end interface circuit; the magnetic sensing matrix comprises several matrix units, and the several matrix units comprises a substrate, a buffer layer, a channel layer, and a barrier layer; a two-dimensional electron gas channel material heterojunction structure composed of the buffer layer, the channel layer, and the barrier layer is sequentially grown on the substrate, and a horizontal Hall element and a switching device are arranged above the channel layer; a main body of the horizontal Hall element is composed of a cross-shaped barrier layer, and four ends of the cross-shaped barrier layer are respectively provided with electrode C1, electrode C2, electrode S1, and electrode S2; the switching device comprises a gate electrode G, a source electrode S, and a drain electrode D; the source electrode S and the drain electrode D are arranged on the channel layer, and the channel layer is provided with a dielectric layer extending to the barrier layer, and the gate electrode G is arranged above the dielectric layer; the electrode C2 is connected to the source electrode S through a metal interconnection line.

2. The high sensitivity magnetic sensing matrix chip with the two-dimensional electronic gas channel structure as described in claim 1, wherein the substrate is one of Si, SiC, and sapphire, or a homogeneous material with the channel layer; the buffer layer is one of AlN and GaN, or a superlattice structure material.

3. The high sensitivity magnetic sensing matrix chip with the two-dimensional electronic gas channel structure as described in claim 1, wherein the channel layer is one of GaN, GaAs, InSb, InAs, and GaO; the barrier layer is the heterojunction material forming a two-dimensional electron gas channel with the channel layer.

4. The high sensitivity magnetic sensing matrix chip with the two-dimensional electronic gas channel structure as described in claim 1, wherein the dielectric layer is one of Al₂O₃, Si₃N₄, SiO₂, and SiON; the metal interconnection line adopts one of copper, tungsten, aluminum and cobalt.

5. The high sensitivity magnetic sensing matrix chip with the two-dimensional electronic gas channel structure as described in claim 1, wherein the thickness of the buffer layer is 10˜100 nm; the thickness of the channel layer is 0.1˜10 μm; the thickness of the barrier layer is 5˜100 nm; and the thickness of the dielectric layer is 20˜50 nm.

6. A high sensitivity magnetic sensing matrix chip circuit with a two-dimensional electronic gas channel structure comprising a power supply module, an excitation power supply circuit, a reference voltage source circuit, an adjustable gain amplifier circuit, a voltage regulation circuit, an AD conversion circuit, a microprocessor, a shift register, and a magnetic sensing matrix, wherein the power supply module is respectively connected with the reference voltage source circuit and the microprocessor; the reference voltage source circuit is respectively connected with the excitation power supply circuit, the adjustable gain amplifier circuit and the voltage regulation circuit; the excitation power supply circuit is sequentially connected with the magnetic sensing matrix, the adjustable gain amplifier circuit, the voltage regulation circuit, the AD conversion circuit, and the microprocessor; the shift register is connected with the magnetic sensing matrix and the microprocessor.

7. The high sensitivity magnetic sensing matrix chip circuit with the two-dimensional electronic gas channel structure as described in claim 6, wherein the magnetic sensing matrix comprises several matrix units, and the several matrix units comprises a substrate, a buffer layer, a channel layer, and a barrier layer; the two-dimensional electron gas channel material heterojunction structure composed of the buffer layer, the channel layer, and the barrier layer is sequentially grown on the substrate, and a horizontal Hall element and a switching device are arranged above the channel layer; a main body of the horizontal Hall element is composed of a cross-shaped barrier layer, and four ends of the cross-shaped barrier layer are respectively provided with electrode C1, electrode C2, electrode S1, and electrode S2; the switching device comprises a gate electrode G, a source electrode S, and a drain electrode D; the source electrode S and the drain electrode D are arranged on the channel layer, and the channel layer is provided with a dielectric layer extending to the barrier layer; the gate electrode G is arranged above the dielectric layer; the electrode C2 is connected to the source electrode S through a metal interconnection line.

8. A method for manufacturing a high sensitivity magnetic sensing matrix chip with a two-dimensional electronic gas channel structure comprising following steps:
S1. cleaning a substrate: preparing a substrate material, cleaning the substrate, and removing contaminants on a surface of the substrate;
S2. epitaxial growth: epitaxially growing a two-dimensional electron gas channel material heterojunction structure and a buffer layer by any one of a metal organic compound chemical vapor deposition method, a molecular beam epitaxy method, and a hydride vapor phase epitaxy method;
S3. mesa etching: after photolithography and development, the epitaxially grown sample is etched by inductively coupled plasma etching;
S4. shallow etching: the sample after mesa etching and isolation, after photolithography and development, are subjected to shallow etching by inductively coupled plasma etching to realize 2DEG contacting the mesa;
S5. fabrication of electrodes by Ohmic contact: after photolithography and development, composite metal is deposited by electron beam evaporation system, and then an excellent ohmic contact is formed by using a rapid thermal annealing process;
S6. gate groove etching: after the electrodes C1, C2, S1, S2, source S, and drain D are prepared, the gate groove etching is carried out by inductively coupled plasma etching method;
S7. gate dielectric deposition: after the sample subjected by gate groove etching is subjected to gate-groove interface treatment using an alkaline solution with nitrogen element, the gate dielectric is deposited by any one of methods of metal-organic chemical vapor deposition, plasma chemical vapor deposition, atomic layer deposition, low pressure chemical vapor deposition, and magnetron sputtering;
S8. fabrication of gate electrode: after photolithography and development, the composite metal is deposited by electron beam evaporation system, and the metal is stripped to form the gate electrode;
S9. surface passivation: use any one of the methods of plasma enhanced chemical vapor deposition, magnetron sputtering, atomic layer deposition, and electron beam evaporation to deposit SiO₂ for device passivation;
S10. Electrodes windowing: photoetching and corroding the passivation layer at the electrode to form an electrode window;
S11. fabrication of metal interconnection lines: after photolithography and development, using the electron beam evaporation system to deposit metal to form the metal interconnection lines;
S12. wire bonding of electrodes: using any one of the methods of magnetron sputtering, electron beam evaporation, and thermal evaporation to deposit metal on the electrodes to make pads and wire bonding.

9. The method for manufacturing the high sensitivity magnetic sensing matrix chip with the two-dimensional electronic gas channel structure as described in claim 8, wherein in step S2, a thickness of the grown channel layer is 0.1˜10 μm, a thickness of the barrier layer grown on the channel layer is 5˜100 nm, and the buffer layer is AlN, GaN or a superlattice structure and a thickness is 10˜100 nm.

10. The method for manufacturing the high sensitivity magnetic sensing matrix chip with the two-dimensional electronic gas channel structure as described in claim 8, wherein in step S3, the etching depth of the mesa is 50˜800 nm; in step S4, the etching depth is 1˜100 nm; in step S6, the etching depth is 1˜100 nm; and in step S7, the deposition thickness is 5˜50 nm.
